(19) United States
(12) Patent Application Publication
(10) Pub. No.: US 2017/0194245 A1
(43) Pub. Date: Jul. 6, 2017

(54) ON-CHIP VARIABLE CAPACITOR WITH GEOMETRIC CROSS-SECTION

(71) Applicant: GLOBALFOUNDRIES Inc., Grand Cayman (KY)

(72) Inventors: Suraj PATIL, Ballston Lake, NY (US); Ajey Poovannummoottil JACOB, Watervliet, NY (US); Shesh Mani PANDEY, Cliffton Park, NY (US)

(73) Assignee: GLOBALFOUNDRIES Inc., Grand Cayman (KY)

(21) Appl. No.: 14/987,211

(22) Filed: Jan. 4, 2016

(51) Int. Cl. H01L 23/522; H01L 21/768; H01L 23/528; H01L 49/02

(52) U.S. Cl. CPC H01L 23/5223; H01L 28/40; H01L 21/76804; H01L 23/5226; H01L 23/5283; H01L 21/76816

(57) ABSTRACT

A method of providing on-chip capacitance includes providing a starting interconnect structure for semiconductor device(s), the starting interconnect structure including a layer of dielectric material. Vias of a same cross-sectional shape are formed in the layer of dielectric material having different and successive geometric cross-sectional size, and capacitors matching the via shape are formed in the vias. The geometric cross-sectional shapes include circles, squares, hexagons and octagons. For the non-circle shapes, a capacitance thereof is approximated by the capacitance of a coaxial capacitor fitting within and touching all sides of the non-circle shape multiplied by a correction factor of about 0.01 to about 2.

### BACKGROUND OF THE INVENTION

Technical Field

The present invention generally relates to variable capacitors. More particularly, the present invention relates to relates to on-chip variable capacitors.

Background Information

CMOS FinFET technology is used to fabricate low power circuits operating at multiple frequency bands. Currently, there are very limited options for on-chip variable capacitors. Traditionally, CMOS on-chip capacitors are non-variable and with limited tunability range for modern day multi-frequency bands chips. Limited tunability restricts re-configurable circuit design and requires multiple passive devices thereby increasing the die layout area. Performance of re-configurable devices are restricted by limited tunable devices on the chip. Currently, semiconductor variable capacitors and MEMS based variable capacitors are used. Semiconductor Variable Capacitors available in a standard CMOS process include—(i) diode varactor, (ii) metal-oxide-semiconductor (MOS) varactor, (iii) switched metal-insulator-metal (MIM) capacitor. Diode Varactor and the MOS varactor have high Q's (>100 at 1 GHz), but the tuning ratios of these varactors are small (<5:1). Switched MIM capacitor, which consists of a MIM capacitor in series with the channel of a metal-oxide-semiconductor field-effect transistor (MOSFET), has a third terminal, the gate of the MOSFET, which controls the capacitance and thus is more linear. Switched MIM capacitors can be designed for large tuning ratios (>5:1), but Q decreases as the tuning ratio increases. This tradeoff occurs because, for large tuning ratios, the MOSFET must be small to minimize parasitic capacitance, but a small MOSFET has high channel resistance, which degrades the Q. None of the semiconductor variable capacitors can simultaneously achieve both large tuning ratio (>10:1) and high Q (>100 at 1 GHz). MEMS Variable Capacitor—Reliability is not guaranteed since RF MEMS can fail from dielectric charging, mechanical creep or fatigue, or from degradation related to repeated mechanical contact. Despite their excellent performance, MEMS variable capacitors are not widely used in RF circuits because most MEMS variable capacitors are not monolithically integrated with CMOS. Monolithic integration is required because the inclusion of MEMS variable capacitors into RF circuits as discrete components is simply too expensive to warrant their use. This requirement is challenging because MEMS fabrication is complicated by the need for integration. The structural and sacrificial layers necessary for MEMS require additional processing beyond that of a standard CMOS process, especially when integration with CMOS is required. Low-temperature micromachining can be used to fabricate MEMS devices directly on top of an existing CMOS process. Alternatively, MEMS can be fabricated on a separate substrate and flip-chip bonded onto a CMOS chip.

Thus, a need continues to exist for capacitors with variable capacitance in semiconductor fabrication.

### SUMMARY OF THE INVENTION

The shortcomings of the prior art are overcome and additional advantages are provided through the provision, in one aspect, of a method of providing on-chip capacitance. The method includes providing a starting interconnect structure for one or more semiconductor devices, the starting interconnect structure including a layer of dielectric material. The method further includes forming at least two vias having a same cross-sectional shape of differing and successive cross-sectional size in the layer of dielectric material, at least one of the at least two vias having a first cross-sectional shape, and forming a geometric capacitor of different capacitance in each of the at least two vias.

In accordance with another aspect, a semiconductor interconnect structure is provided. The semiconductor interconnect structure includes an interconnect structure for one or more semiconductor devices, the interconnect structure including a layer of dielectric material with at least two vias of differing and successive cross-sectional size therein, the at least two vias having a geometric cross-sectional shape, and a shaped capacitor in each via matching the geometric cross-sectional shape of the at least two vias, a capacitance thereof increasing with increasing cross-sectional size.

In accordance with yet another aspect, a semiconductor structure is provided. The semiconductor structure includes one or more semiconductor devices on a substrate, and a semiconductor interconnect structure above the one or more semiconductor devices electrically coupled thereto, the semiconductor interconnect structure including at least two shaped capacitors of differing and successive cross-sectional size having a geometric cross-sectional shape and an increasing capacitance with increased cross-sectional size.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of a starting semiconductor interconnect structure for one or more semiconductor devices (not shown), the starting interconnect structure including a metal layer and a dielectric layer, in accordance with one or more aspects of the present invention.

FIG. 2 depicts one example of the starting semiconductor interconnect structure 100 of FIG. 1 after a via is formed in a dielectric layer for a variable coaxial capacitor, in accordance with one or more aspects of the present invention.

FIG. 3 depicts one example of the semiconductor interconnect structure of FIG. 2 after forming an outer layer of metal in the via and extending it over the dielectric layer, in accordance with one or more aspects of the present invention.

FIG. 4 depicts one example of the semiconductor interconnect structure of FIG. 3 after forming a middle layer of dielectric material and extending the middle layer over a surface of the outer layer of metal, in accordance with one or more aspects of the present invention.

FIG. 5 depicts one example of the semiconductor interconnect structure of FIG. 4 after forming an inner metal layer in the via and extending the metal layer over the extended middle layer of dielectric material, in accordance with one or more aspects of the present invention.

FIG. 6 depicts one example of the semiconductor interconnect structure of FIG. 5 in three different sizes, each differing from the others only in a top width, respectively, of the inner layer of metal, with all other dimensions constant, resulting in different capacitances for each coaxial capacitor, each coaxial capacitor having a via angle between about 75 degrees and about 90 degrees, in accordance with one or more aspects of the present invention.

FIG. 7 is a top-down view of one example of the semiconductor interconnect structure of FIG. 6, showing a first radius from a center of coaxial capacitor to an outer edge of the inner metal layer, and a second radius from the center to an outer edge of the middle layer of dielectric material, in accordance with one or more aspects of the present invention.

FIG. 8 is a cross-sectional view of one example of a semiconductor structure, the semiconductor structure including a substrate with semiconductor device(s) separated by a dielectric material above which and electrically coupled thereto is a coaxial capacitor and a top and bottom metal layers, the coaxial capacitor including an inner metal layer, a middle dielectric layer and an outer metal layer.

FIG. 9 is a cross-sectional view of one example of a square capacitor according to the present invention having a square cross-sectional shape, the capacitance of which can be approximated using a circular cross-section coaxial capacitor fitting within and in contact with all sides of the square capacitor multiplied by a correction factor, the coaxial capacitor including an outer ring boundary and an inner ring boundary, and the square capacitor including an outer square layer, middle square layer and an inner square layer, the outer ring boundary fitting within and touching all sides of the outer square layer and the inner ring boundary fitting within and touching all sides of the inner square layer.

FIG. 10 is a cross-sectional view of one example of a hexagon capacitor according to the present invention having a hexagon cross-sectional shape, the capacitance of which can be approximated using a circular cross-section coaxial capacitor fitting within the hexagon capacitor multiplied by a correction factor, the coaxial capacitor including an outer ring boundary and an inner ring boundary, and the hexagon capacitor including an outer hexagon layer, middle hexagon layer and an inner hexagon layer, the outer ring boundary fitting within and touching all sides of the outer hexagon layer and the inner ring boundary fitting within and touching all sides of the inner hexagon layer.

FIG. 11 is a cross-sectional view of one example of a octagon capacitor according to the present invention having a octagon cross-sectional shape, the capacitance of which can be approximated using a circular cross-section coaxial capacitor fitting within the octagon capacitor multiplied by a correction factor, the coaxial capacitor including an outer ring boundary and an inner ring boundary, and the octagon capacitor including an outer octagon layer, middle octagon layer and an inner octagon layer, the outer ring boundary fitting within and touching all sides of the outer octagon layer and the inner ring boundary fitting within and touching all sides of the inner octagon layer.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

As used herein, unless otherwise specified, the term “about” used with a value, such as measurement, size, etc., means a possible variation of plus or minus five percent of the value. Also, unless otherwise specified, a given aspect of semiconductor fabrication described herein may be accomplished using conventional processes and techniques, where part of a method, and may include conventional materials appropriate for the circumstances, where a semiconductor structure is described.

Reference is made below to the drawings, which are not drawn to scale for ease of understanding, wherein the same reference numbers are used throughout different figures to designate the same or similar components.

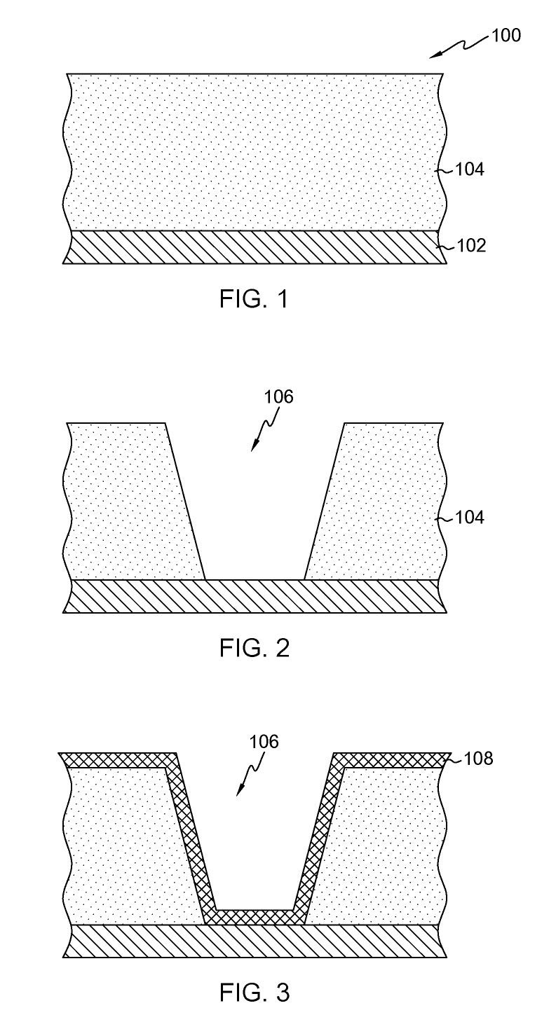

FIG. 1 is a cross-sectional view of one example of a starting semiconductor interconnect structure 100 for one or more semiconductor devices (not shown), the starting interconnect structure including a metal layer 102 and a dielectric layer 104, in accordance with one or more aspects of the present invention.

The starting structure may be conventionally fabricated, for example, using known processes and techniques. Further, unless noted otherwise, conventional processes and techniques may be used to achieve individual steps of the fabrication process of the present invention. However, although only a portion is shown for simplicity, it will be understood that, in practice, many such structures are typically included on the same bulk substrate.

The dielectric layer may include, for example, hafnium dioxide HfO₂ having a dielectric constant of between 22 and 25, zirconium dioxide ZrO₂ having a dielectric constant of 22 and 25, strontium titanate SrTiO₃ (250 to 300), titanium dioxide TiO₂ (80), barium strontium titanate BaxSryTiO3 (1000 to 1250) or one or more combinations thereof.

FIG. 2 depicts one example of the starting semiconductor interconnect structure 100 of FIG. 1 after a via 106 is formed in dielectric layer 104 for a variable coaxial capacitor, in accordance with one or more aspects of the present invention.

FIG. 3 depicts one example of the semiconductor interconnect structure of FIG. 2 after forming an outer layer of metal 108 in via 106 and extending it over the dielectric layer 104, in accordance with one or more aspects of the present invention.

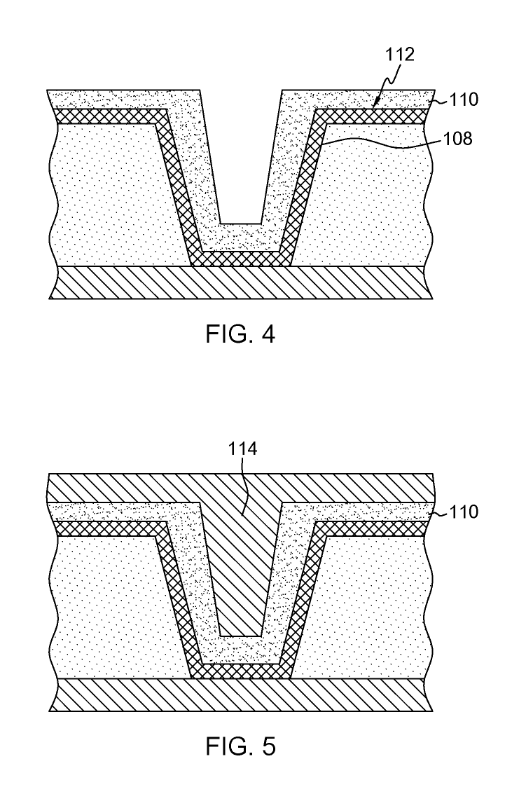

FIG. 4 depicts one example of the semiconductor interconnect structure of FIG. 3 after forming a middle layer of dielectric material 110 and extending the middle layer over a surface 112 of the outer layer of metal 108, in accordance with one or more aspects of the present invention.

FIG. 5 depicts one example of the semiconductor interconnect structure of FIG. 4 after forming an inner metal layer 114 in the via and extending the metal layer over the extended middle layer of dielectric material 110, in accordance with one or more aspects of the present invention.

The metal used with the present invention includes, for example, copper, layered tantalum and tantalum nitride, layered titanium and titanium nitride, tungsten, cobalt, aluminum or nickel.

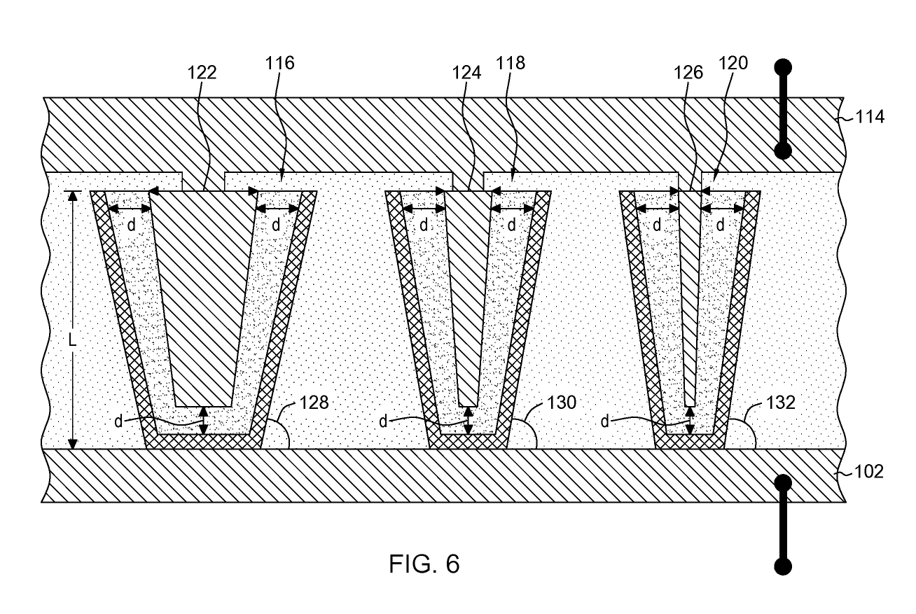

FIG. 6 depicts one example of the semiconductor interconnect structure of FIG. 5 in three different sizes 116, 118 and 120, each differing from the others only in a top width 122, 124 and 126, respectively, of the inner layer of metal 114, with all other dimensions constant, resulting in different capacitances for each coaxial capacitor, each coaxial capacitor having a via angle 128, 130 and 132 between about 75 degrees (128) and about 90 degrees (132), in accordance with one or more aspects of the present invention.

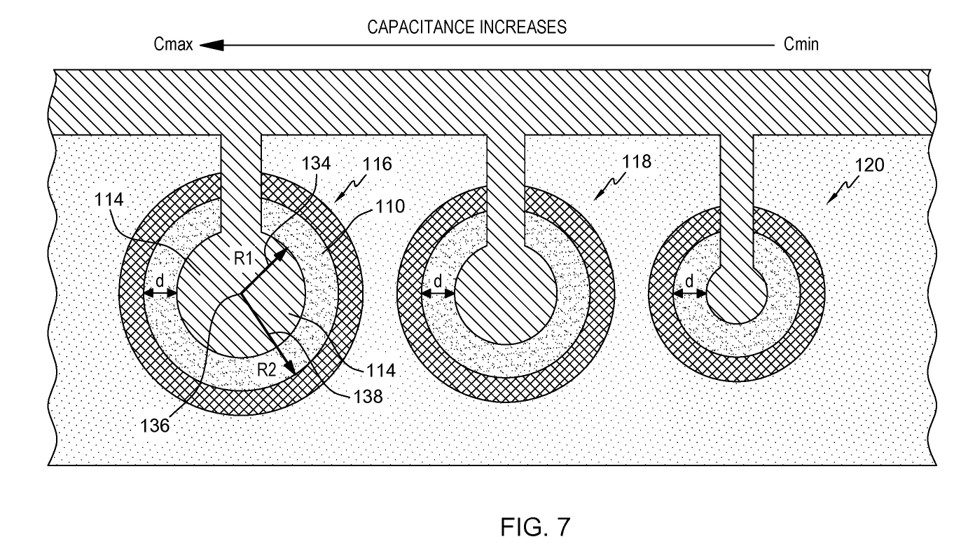

FIG. 7 is a top-down view of one example of the semiconductor interconnect structure of FIG. 6, showing a first radius 134 from a center 136 of coaxial capacitor 116 to an outer edge of inner metal layer 114, and a second radius 138 from the center to an outer edge of the middle layer of dielectric material 110, in accordance with one or more aspects of the present invention.

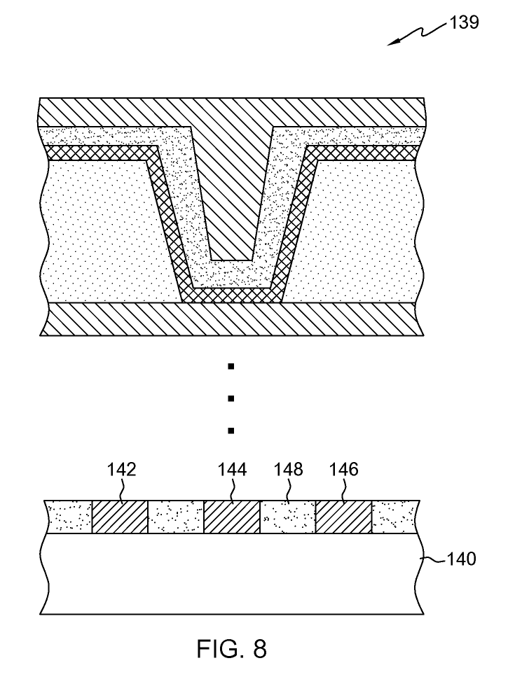

FIG. 8 is a cross-sectional view of one example of a semiconductor structure 139, the semiconductor structure including a substrate 140 with semiconductor device(s) (here, devices 142, 144 and 146) separated by a dielectric material 148 above which and electrically coupled thereto is a coaxial capacitor 150 and top 151 and bottom 153 metal layers, the coaxial capacitor including an inner metal layer 152, a middle dielectric layer 154 and an outer metal layer 156.

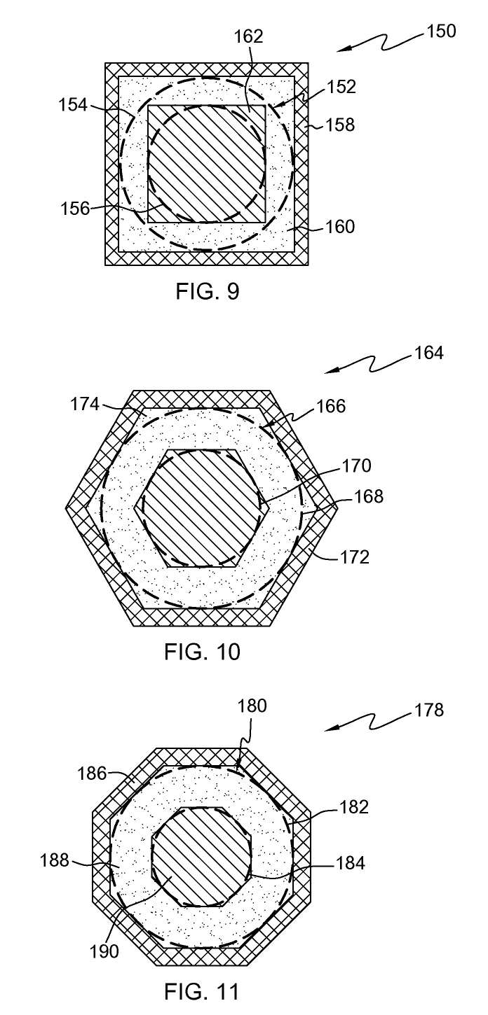

FIG. 9 is a cross-sectional view of one example of a square capacitor 150 according to the present invention having a square cross-sectional shape, the capacitance of which can be approximated using a circular cross-section coaxial capacitor 152 fitting within and in contact with all sides of the square capacitor multiplied by a correction factor, the coaxial capacitor including an outer ring boundary 154 and an inner ring boundary 156, and the square capacitor including an outer square layer 158, middle square layer 160 and an inner square layer 162, the outer ring boundary fitting within and touching all sides of the outer square layer and the inner ring boundary fitting within and touching all sides of the inner square layer.

FIG. 10 is a cross-sectional view of one example of a hexagon capacitor 164 according to the present invention having a hexagon cross-sectional shape, the capacitance of which can be approximated using a circular cross-section coaxial capacitor 166 fitting within the hexagon capacitor multiplied by a correction factor, the coaxial capacitor including an outer ring boundary 168 and an inner ring boundary 170, and the hexagon capacitor including an outer hexagon layer 172, middle hexagon layer 174 and an inner hexagon layer 176, the outer ring boundary fitting within and touching all sides of the outer hexagon layer and the inner ring boundary fitting within and touching all sides of the inner hexagon layer.

FIG. 11 is a cross-sectional view of one example of a octagon capacitor 178 according to the present invention having a octagon cross-sectional shape, the capacitance of which can be approximated using a circular cross-section coaxial capacitor 180 fitting within the octagon capacitor multiplied by a correction factor, the coaxial capacitor including an outer ring boundary 182 and an inner ring boundary 184, and the octagon capacitor including an outer octagon layer 186, middle octagon layer 188 and an inner octagon layer 190, the outer ring boundary fitting within and touching all sides of the outer octagon layer and the inner ring boundary fitting within and touching all sides of the inner octagon layer.

In a first aspect, disclosed above is a method. The method includes providing a starting interconnect structure for semiconductor device(s), the starting structure including a layer of dielectric material. The method further includes forming vias having a same cross-sectional shape in the layer of dielectric material, the vias having different and successive geometric cross-sectional size, and forming capacitors of different capacitance in the vias.

In one example, the first cross-sectional shape may include, for example, a circle, and each geometric capacitor of the at least one of the multiple vias may include, for example, a coaxial capacitor.

In one example, forming the coaxial capacitor may include, for example, forming an outer layer within the via of diffusion barrier material and/or metal, forming a middle layer of dielectric material with a dielectric constant above 3.9, and forming a center layer of metal.

In one example, a capacitance of each coaxial capacitor may be, for example, determined by a radius measured from a center thereof to an outer edge of the center layer of metal, and all other dimensions of all the capacitor(s) being constant.

In one example, the first cross-sectional shape in the method of the first aspect may include, for example, a square shape.

In one example, a capacitance of each square capacitor in the at least one of the multiple vias may be, for example, approximated by a capacitance of a coaxial capacitor fitting within and touching all sides of the square multiplied by a correction factor. In one example, the correction factor may be, for example, from about 0.01 to about 2.

In one example, each coaxial capacitor may include, for example, an outer layer of metal, a middle layer of dielectric material and a center layer of metal, and a capacitance of each coaxial capacitor may be, for example, determined by a radius measured from a center thereof to an outer edge of the center layer of metal, and all other dimensions of all the coaxial capacitors being constant.

In one example, the first cross-sectional shape in the method of the first aspect may include, for example, a hexagon shape.

In one example, a capacitance of each hexagon capacitor in the at least one of the multiple vias may be, for example, approximated by a capacitance of a coaxial capacitor fitting within and touching all sides of the hexagon multiplied by a correction factor. In one example, the correction factor may be, for example, from about 0.01 to about 2.

In one example, each coaxial capacitor may include, for example, an outer layer of metal, a middle layer of dielectric material and a center layer of metal, and a capacitance of each coaxial capacitor may be, for example, determined by a radius measured from a center thereof to an outer edge of the center layer of metal, and all other dimensions of all the coaxial capacitors being constant.

In one example, the first cross-sectional shape in the method of the first aspect may include, for example, a octagon shape.

In one example, a capacitance of each octagon capacitor in the at least one of the multiple vias may be, for example, approximated by a capacitance of a coaxial capacitor fitting within and touching all sides of the octagon multiplied by a correction factor. In one example, the correction factor may be, for example, from about 0.01 to about 2.

In one example, each coaxial capacitor includes an outer layer of metal, a middle layer of dielectric material and a center layer of metal, and a capacitance of each coaxial capacitor may be, for example, determined by a radius measured from a center thereof to an outer edge of the center layer of metal, and all other dimensions of all the coaxial capacitors being constant.

In a second aspect, disclosed above is a semiconductor interconnect structure. The semiconductor interconnect structure includes an interconnect structure for semiconductor device(s), the interconnect structure including a layer of dielectric material with multiple vias of differing and successive cross-sectional size therein, the at least two vias having a geometric cross-sectional shape, and a shaped capacitor in each via matching the geometric cross-sectional shape of the multiple vias, a capacitance thereof increasing with increasing cross-sectional size.

In one example, the geometric cross-sectional shape may include, for example, one of a circular cross-sectional shape, a square cross-sectional shape, a hexagon cross-sectional shape and an octagon cross-sectional shape.

In a third aspect, disclosed above is a semiconductor structure. The semiconductor structure includes semiconductor device(s) on a substrate, and a semiconductor interconnect structure above the semiconductor device(s) electrically coupled thereto, the semiconductor interconnect structure including multiple shaped capacitors of differing and successive cross-sectional size having a geometric cross-sectional shape and an increasing capacitance with increased cross-sectional size.

In one example, the geometric cross-sectional shape may include, for example, one of a circular cross-sectional shape, a square cross-sectional shape, a hexagon cross-sectional shape and an octagon cross-sectional shape.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting interconnect structure for one or more semiconductor devices, the starting interconnect structure comprising a layer of dielectric material;
forming at least two vias having a same cross-sectional shape, a first via of the at least two vias being of differing cross-sectional size in the layer of dielectric material than a second via of the at least two vias, wherein at least one of the at least two vias has a first cross-sectional shape; and
forming a geometric capacitor of different capacitance in each of the first via and the second via of the at least two vias.

2. The method of claim 1, wherein the first cross-sectional shape comprises a circle, and wherein each geometric capacitor of the at least one of the at least two vias comprises a coaxial capacitor.

3. The method of claim 2, wherein forming each coaxial capacitor comprises:
forming an outer layer within the via of diffusion barrier material and/or metal;
forming a middle layer of dielectric material with a dielectric constant above 3.9; and
forming a center layer of metal.

4. The method of claim 3, wherein a capacitance of each coaxial capacitor is determined by a radius measured from a center thereof to an outer edge of the center layer of metal, and wherein all other dimensions of all the coaxial capacitors is constant.

5. The method of claim 1, wherein the first cross-sectional shape comprises a square shape.

6. The method of claim 5, wherein a capacitance of each square capacitor in the at least one of the at least two vias is approximated by a capacitance of a coaxial capacitor fitting within and touching all sides of the square multiplied by a correction factor.

7. The method of claim 6, wherein the correction factor comprises from about 0.01 to about 2.

8. The method of claim 7, wherein each coaxial capacitor comprises an outer layer of metal, a middle layer of dielectric material and a center layer of metal, wherein a capacitance of each coaxial capacitor is determined by a radius measured from a center thereof to an outer edge of the center layer of metal, and wherein all other dimensions of all the coaxial capacitors is constant.

9. The method of claim 1, wherein the first cross-sectional shape comprises a hexagon shape.

10. The method of claim 9, wherein a capacitance of each hexagon capacitor in the at least one of the at least two vias is approximated by a capacitance of a coaxial capacitor fitting within and touching all sides of the hexagon multiplied by a correction factor.

11. The method of claim 10, wherein the correction factor comprises from about 0.01 to about 2.

12. The method of claim 11, wherein each coaxial capacitor comprises an outer layer of metal, a middle layer of dielectric material and a center layer of metal, wherein a capacitance of each coaxial capacitor is determined by a radius measured from a center thereof to an outer edge of the center layer of metal, and wherein all other dimensions of all the coaxial capacitors is constant.

13. The method of claim 1, wherein the first cross-sectional shape comprises a octagon shape.

14. The method of claim 13, wherein a capacitance of each octagon capacitor in the at least one of the at least two vias is approximated by a capacitance of a coaxial capacitor fitting within and touching all sides of the octagon multiplied by a correction factor.

15. The method of claim 14, wherein the correction factor comprises from about 0.01 to about 2.

16. The method of claim 15, wherein each coaxial capacitor comprises an outer layer of metal, a middle layer of dielectric material and a center layer of metal, wherein a capacitance of each coaxial capacitor is determined by a radius measured from a center thereof to an outer edge of the center layer of metal, and wherein all other dimensions of all the coaxial capacitors is constant.

17. A semiconductor interconnect structure, comprising:
an interconnect structure for one or more semiconductor devices, the interconnect structure comprising a layer of dielectric material with at least two vias of differing and successive cross-sectional size therein, wherein the at least two vias have a geometric cross-sectional shape; and
a shaped capacitor in each via matching the geometric cross-sectional shape of the at least two vias, a capacitance thereof increasing with increasing cross-sectional size.

18. The semiconductor interconnect structure of claim 17, wherein the geometric cross-sectional shape comprises one of a circular cross-sectional shape, a square cross-sectional shape, a hexagon cross-sectional shape and an octagon cross-sectional shape.

19. A semiconductor structure, comprising:
one or more semiconductor devices on a substrate; and
a semiconductor interconnect structure above the one or more semiconductor devices electrically coupled thereto, the semiconductor interconnect structure comprising at least two shaped capacitors of differing and successive cross-sectional size having a geometric cross-sectional shape and an increasing capacitance with increased cross-sectional size.

20. The semiconductor interconnect structure of claim 19, wherein the geometric cross-sectional shape comprises at least one of a circular cross-sectional shape, a square cross-sectional shape, a hexagon cross-sectional shape and an octagon cross-sectional shape.
